(19) United States
(12) Patent Application Publication
(10) Pub. No.: US 2024/0431179 A1
(43) Pub. Date: Dec. 26, 2024

(54) DISPLAY PANEL AND PERSONAL IMMERSIVE DEVICE INCLUDING THE SAME

(71) Applicant: LG DISPLAY CO., LTD., Seoul (KR)

(72) Inventors: Min Ki KIM, Paju-si (KR); Hye Min HWANG, Paju-si (KR); Jae Hwan MYUNG, Paju-si (KR)

(73) Assignee: LG DISPLAY CO., LTD., Seoul (KR)

(21) Appl. No.: 18/674,454

(22) Filed: May 24, 2024

(30) Foreign Application Priority Data
Jun. 22, 2023 (KR) 10-2023-0080393

(51) Int. Cl. H10K 59/80; G06F 3/01; G06T 19/00; H10K 59/35; H10K 59/38; H10K 102/00; H10K 102/10

(52) U.S. Cl. CPC H10K 59/80518; H10K 59/35; H10K 59/38; H10K 59/80524; H10K 59/873; G06F 3/011; G06T 19/006; H10K 2102/101; H10K 2102/351

(57) ABSTRACT

A display panel and a personal immersive device including the same are disclosed. In the display panel, any one of a first electrode and a second electrode of a light-emitting element includes: an incident-side metal layer on which light is incident; a reflective-side metal layer from which the light is reflected; and a transparent intermediate layer interposed between the incident-side metal layer and the reflective-side metal layer.

### CROSS-REFERENCE TO RELATED APPLICATION

This application claims priority to and the benefit of Korean Patent Application No. 10-2023-0080393, filed on Jun. 22, 2023, the disclosure of which is incorporated herein by reference in its entirety for all purpose.

### BACKGROUND

### 1. Technical Field

The present disclosure relates to a display panel and a personal immersive device including the same, and more particularly, for example, without limitation, to a display panel capable of reducing particular light exposed to a user, and a personal immersive device using the same.

### 2. Discussion of the Related Art

Personal immersive devices have been developed in various forms such as head mounted display (HMD), face mounted display (FMD), and eye glasses-type display (EGD). The personal immersive devices are divided into virtual reality (VR) devices and augmented reality (AR) devices.

In the personal immersive device, a distance between user's eyes and a display panel is small. A display device of such a personal immersive device requires high resolution, high luminance, and low power operation.

Each pixel of the display panel may include a red sub-pixel, a green sub-pixel, and a blue sub-pixel to implement color. Since blue light adversely affects the human retina, prolonged exposure of a user to blue light may cause eye fatigue, dry eyes, sleep disturbances, or the like. In particular, in the personal immersive device, since the distance between the user's eyes and the display panel is small, blue light has more damaging on the user's eyes.

The description provided in the description of the related art section should not be assumed to be prior art merely because it is mentioned in or associated with the description of the related art section. The description of the related art section may include information that describes one or more aspects of the subject technology, and the description in this section does not limit the invention.

### SUMMARY

Accordingly, embodiments of the present disclosure are directed to a display panel and a personal immersive device including the same that substantially obviate one or more of the problems due to limitations and disadvantages of the related art.

An aspect of the present disclosure is to provide a display panel capable of reducing light of a specific wavelength, e.g., blue light, exposed to a user, and a personal immersive device using the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a display panel may comprise a light-emitting element configured to emit light in response to a voltage applied to a first electrode and a second electrode. Any one of the first electrode and the second electrode includes: an incident-side metal layer on which light from the light-emitting element is incident; a reflective-side metal layer from which the light is reflected; and a transparent intermediate layer interposed between the incident-side metal layer and the reflective-side metal layer.

The incident-side metal layer is thinner than the reflective-side metal layer.

The incident-side metal layer may have a thickness between 50 Å and 450 Å, and the reflective-side metal layer may have a thickness between 500 Å and 2000 Å.

Each of the incident-side metal layer and the reflective-side metal layer may include metal selected from silver (Ag), gold (Au), and aluminum (Al).

The transparent intermediate layer may have a thickness between 50 nm and 80 nm or a thickness between 140 nm and 160 nm.

The transparent intermediate layer may include a single layer selected from a transparent conductive oxide, an inorganic insulating material, and an organic insulating material, or a stacked structure in which at least two of the transparent conductive oxide, the inorganic insulating material, and the organic insulating material are stacked.

In another aspect, a display panel may comprise a light-emitting element layer in which a light-emitting element is disposed; a circuit layer disposed below the light-emitting element layer and including a pixel circuit configured to drive the light-emitting element; and an encapsulation layer disposed on the light-emitting element layer. The light-emitting element layer includes a plurality of first electrodes disposed respectively in a red sub-pixel, a green sub-pixel, and a blue sub-pixel and separated between the sub-pixels; and a second electrode shared by the red sub-pixel, the green sub-pixel, and the blue sub-pixel. Any one of the first electrode and the second electrode includes an incident-side metal layer on which light from the light-emitting element is incident; a reflective-side metal layer from which the light is reflected; and a transparent intermediate layer interposed between the incident-side metal layer and the reflective-side metal layer.

The incident-side metal layer is thinner than the reflective-side metal layer.

The light-emitting element may include a white light-emitting element disposed in the red sub-pixel, the green sub-pixel, and the blue sub-pixel to emit white light. The red sub-pixel may include a red color filter disposed on the encapsulation layer or below the first electrode of the red sub-pixel. The green sub-pixel may include a green color filter disposed on the encapsulation layer or below the first electrode of the green sub-pixel. The blue sub-pixel may include a blue color filter disposed on the encapsulation layer or below the first electrode of the blue sub-pixel.

The circuit layer may include an insulating layer adjacent to the first electrodes. The insulating layer may be recessed between the sub-pixels. The light-emitting element layer may include an insulating layer pattern that covers a top surface and a side surface of an edge of each of the first electrodes.

In another aspect, a display panel may comprise a light-emitting element layer in which a light-emitting element is disposed; a circuit layer disposed below the light-emitting element layer and including a pixel circuit configured to drive the light-emitting element; and an encapsulation layer disposed on the light-emitting element layer. The light-emitting element layer includes a plurality of first electrodes disposed respectively in a red sub-pixel, a green sub-pixel, and a blue sub-pixel and separated between the sub-pixels; and a second electrode shared by the red sub-pixel, the green sub-pixel, and the blue sub-pixel. The red sub-pixel includes a first reflective layer disposed below the first electrode of the red sub-pixel. The green sub-pixel includes a second reflective layer disposed below the first electrode of the green sub-pixel. The blue sub-pixel includes a third reflective layer disposed below the first electrode of the blue sub-pixel. At least the third reflective layer of the first reflective layer, the second reflective layer, the third reflective layer includes an incident-side metal layer on which light from the light-emitting element is incident; a reflective-side metal layer from which the light is reflected; and a transparent intermediate layer interposed between the incident-side metal layer and the reflective-side metal layer.

The incident-side metal layer is thinner than the reflective-side metal layer.

Each of the first reflective layer, the second reflective layer, and the third reflective layer may include the incident-side metal layer, the reflective-side metal layer, and the transparent intermediate layer.

An insulating layer between the first reflective layer and the first electrode of the red sub-pixel may be thicker than an insulating layer between the second reflective layer and the first electrode of the green sub-pixel.

The third reflective layer and the first electrode of the blue sub-pixel may be in contact with each other.

According to one or more embodiments of the present disclosure a personal immersive device includes the display panel.

According to the present disclosure, light in a wavelength band that adversely affects the user's eyes may be absorbed in a reflective layer and the thickness of the metal layer of the reflective layer may be adjusted to appropriately adjust an absorption rate, transmittance, and reflectance of light. Therefore, the present disclosure may selectively reduce or minimize light in a blue wavelength band that adversely affects the user's eye health among light incident on the user's eyes from pixels of the display panel, without degrading the image quality perceived by the user.

According to the present disclosure, it is possible to implement a display device capable of being driven at low power by reducing light loss and reducing a leakage current flowing between sub-pixels.

According to the present disclosure, it is possible to prevent degradation of the light-emitting element by forming a fence at the edge of the electrode.

The effects of the present disclosure are not limited to those mentioned above, and other effects not mentioned will be clearly understood by those skilled in the art from the description of the claims.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view illustrating a pixel of a display panel according to one exemplary embodiment of the present disclosure;

FIG. 2 is a cross-sectional view schematically illustrating an example of a cross-sectional structure of a pixel taken along line I-I′ of FIG. 1 in a top emission type display panel;

FIG. 3 is a cross-sectional view schematically illustrating an example of a cross-sectional structure of a pixel taken along line I-I′ of FIG. 1 in a bottom emission type display panel;

FIG. 4 is a cross-sectional view illustrating a cross-sectional structure of a reflective layer capable of absorbing light in an absorption wavelength band according to one exemplary embodiment of the present disclosure;

FIGS. 5 and 6 are graphs illustrating an absorption rate of light for each wavelength depending on the thickness of a transparent intermediate layer, while the thicknesses of an incident-side metal layer and a reflective-side metal layer are fixed;

FIG. 7 is a graph illustrating a transmittance of light for each wavelength depending on the thickness of silver (Ag);

FIG. 8 is a graph illustrating an absorption rate of light for each wavelength depending on the thickness of a reflective-side metal layer in a reflective layer;

FIG. 9 is a graph illustrating a transmittance of light for each wavelength depending on the thickness of a reflection-side metal layer in a reflective layer;

FIG. 10 is a graph illustrating a reflectance of light for each wavelength depending on the thickness of a reflection-side metal layer in a reflective layer;

FIG. 11 is a cross-sectional view illustrating another example to which the reflective layer shown in FIG. 4 is applied in a top emission type display panel;

FIG. 12 is a cross-sectional view illustrating another example to which the reflective layer shown in FIG. 4 is applied in a bottom emission type display panel;

FIGS. 13 and 14 are cross-sectional views illustrating still other examples to which the reflective layer shown in FIG. 4 is applied in a top emission type display panel;

FIG. 15 is a diagram illustrating an example of the appearance of a personal immersive device; and

FIG. 16 is a block diagram illustrating an example of a display device applicable to a personal immersive device.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure and methods for accomplishing the same will be more clearly understood from exemplary embodiments described below with reference to the accompanying drawings. However, the present disclosure is not limited to the following exemplary embodiments, but may be implemented in various different forms; rather, the present embodiments will make the disclosure of the present disclosure complete and allow those skilled in the art to fully comprehend the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the present specification. Further, in describing the present disclosure, detailed descriptions of known related technologies may be omitted to avoid unnecessarily obscuring the subject matter of the present disclosure.

The terms such as “comprising,” “including,” “having,” and “make up of,” “formed of,” “containing” and the like used herein are generally intended to allow other components to be added unless the terms are used with the term “only.” Any references to singular may include plural unless expressly stated otherwise.

Components are interpreted to include an ordinary error range even if not expressly stated.

When a positional or interconnected relationship is described between two components, such as “on top of,” “over,” “above,” “below,” “beneath” “next to,” “beside,” “connect or couple with,” “crossing,” “intersecting,” or the like, one or more other components may be interposed between them, unless “immediately” or “directly” is used. For example, where an element or layer is disposed “on” another element or layer, a third layer or element may be interposed therebetween.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

When a temporal antecedent relationship is described, such as “after”, “following”, “next to”, “before”, or the like, it may not be continuous on a time base unless “just”, “immediately” or “directly” is used.

The terms “first,” “second,” “A,” “B,” “(a),” and “(b),” and the like may be used to distinguish elements from each other, but the functions or structures of the components are not limited by ordinal numbers or component names in front of the components. For example, a first element could be termed a second element, and, similarly, a second element could be termed a first element, without departing from the scope of the present disclosure.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

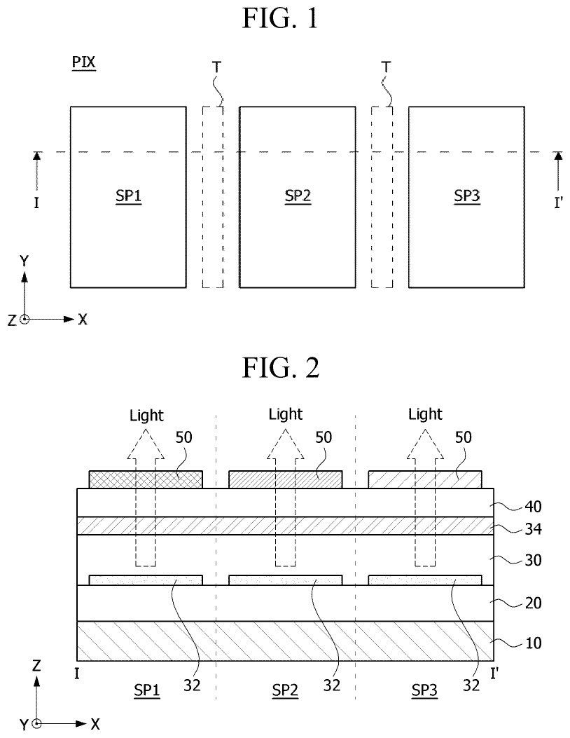

Referring to FIGS. 1 to 3, a display panel according to an exemplary embodiment of the present disclosure has a length extending in the X-axis direction, a width extending in the Y-axis direction, and a thickness extending in the Z-axis direction. The display panel may be rectangular when viewed in plan view, or may have a variant shape that includes at least a portion that is curved or elliptical.

A substrate 10 of the display panel may be manufactured based on glass, plastic, flexible polymer film, silicon wafer, or the like. The substrate 10 may be construed as a backplane. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

A plurality of pixels PIX are disposed on the display panel. Each of the plurality of pixels PIX may emit light having different wavelengths from each other. The plurality of sub pixels may include first to third sub pixels which emit different color light from each other. For example, each of the pixels PIX may include a red (R) sub-pixel SP1 which is a first sub-pixel, a green (G) sub-pixel SP2 which is a second sub-pixel, and a blue (B) sub-pixel SP3 which is a third sub-pixel for color implementation. Further, each of the pixels may further include a white (W) sub-pixel, but are not limited thereto. The size or shape of each of the plurality of sub-pixels, such as sub-pixels SP1, SP2, and SP3, may be variously modified. A recessed trench T may be disposed between the adjacent sub-pixels SP1, SP2, and SP3. The trench T blocks a current flowing between the adjacent sub-pixels. The trench T may block a leakage current flowing to the sub-pixel by lengthening a current path between the adjacent sub-pixels SP1, SP2, and SP3.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the example embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

A circuit layer 20, a light-emitting element layer 30, and an encapsulation layer 40 may be stacked on the substrate 10. For example, the circuit layer 20 may be disposed over the substrate 10, the light-emitting element layer 30 may be disposed over the circuit layer 20, and the encapsulation layer 40 may be disposed over the light-emitting element layer 30. Embodiments are not limited thereto. As an example, at least one of the above-mentioned components may be omitted, and/or one or more additional components could be further included.

The circuit layer 20 may include a pixel circuit that drives light-emitting elements of the sub-pixels SP1, SP2, and SP3 based on pixel data of an input image. The circuit layer 20 may further include a gate driving circuit that supplies a gate signal to the pixel circuit. The pixel circuit may include a driving transistor that supplies a current to the light-emitting element based on its gate-source voltage, a switching transistor that applies a data voltage of the pixel data to the gate or source of the driving transistor, a storage capacitor that maintains the gate-source voltage of the driving transistor, a plurality of insulating layers that insulate metal patterns of such circuit elements, and the like. For example, the driving transistor, switching transistor in the pixel circuit may be implemented as PMOS (P-channel metal-oxide-semiconductor) or NMOS (N-channel metal-oxide-semiconductor).

The light-emitting element layer 30 may include a light-emitting element disposed in each of the sub-pixels SP1, SP2, and SP3 and driven by the pixel circuit. In one exemplary embodiment, the light-emitting element may be a white light-emitting element that is commonly disposed in the sub-pixels SP1, SP2, and SP3 to generate white light, when the light-emitting layer includes a white organic light-emitting element, a color filter for converting white light from the white organic light-emitting element into light of a different color may be disposed on the light-emitting layer. In another exemplary embodiment, a red light-emitting element that generates red light may be disposed in the red sub-pixel SP1, and a green light-emitting element that generates green light may be disposed in the green sub-pixel SP2. A blue light-emitting element that generates blue light may be disposed in the blue sub-pixel SP3.

When the white light-emitting element is disposed in the sub-pixels SP1, SP2, and SP3, a color filter 50 may be disposed to selectively transmit a wavelength of each color. The light-emitting elements of the light-emitting element layer 30 may be covered by multiple passivation layers including organic and inorganic layers. For example, the multiple passivation layers may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The light-emitting element may be implemented as an organic light-emitting element or an inorganic light-emitting element. For example, the light-emitting element of the light-emitting element layer 30 may be implemented with an organic light-emitting diode (OLED) or an inorganic LED. The light-emitting element may include a first electrode 32, a second electrode 34, and an emission layer formed between the electrodes 32 and 34. The first electrode 32 may be an anode electrode of the light-emitting element separated for each sub-pixel, but are not limited thereto. In other words, each of the plurality of first electrodes 32 is disposed in each of the subpixels SP1, SP2, and SP3, respectively, as shown in FIG. 2. The second electrode 34 may be a common electrode shared by the plurality of sub-pixels, such as subpixels SP1, SP2, and SP3. The second electrode 34 may be a cathode electrode of the light-emitting element, but are not limited thereto.

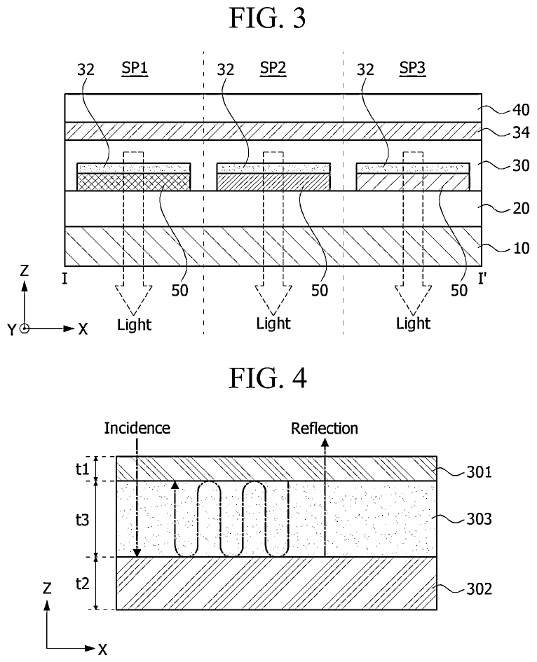

As shown in FIG. 2, the first electrodes 32 of the light-emitting element layer 30 may be disposed on the circuit layer 20, the second electrode 34 of the light-emitting element layer 30 may be disposed below the encapsulation layer 40, and the color filters 50 may be disposed on the encapsulation layer 40. As shown in FIG. 3, the color filters 50 may be disposed on the circuit layer 20, the first electrode 32 of the light-emitting element layer 30 may be disposed the color filter 50, and the second electrode 34 of the light-emitting element layer 30 may be disposed below the encapsulation layer 40.

The encapsulation layer 40 covers the light-emitting element layer 30 to seal the circuit layer 20 and the light-emitting element layer 30. As an example, the encapsulation layer 40 may have a multi-insulating layer structure in which an organic layer and an inorganic layer are alternately stacked for example, the encapsulation layer 40 may have a structure in which at least one organic layer is disposed between two inorganic layers. The inorganic layer blocks the permeation of moisture or oxygen, the inorganic layers may include an inorganic insulating material. For example, the inorganic layers may include an inorganic insulating material capable of low-temperature deposition, such as silicon nitride (SiN), silicon oxide (SiO), silicon oxynitride (SiON) and aluminum oxide (AlO). The organic layer flattens the surface of the inorganic layer, the organic layer may include an organic insulating material, such as acrylic resin, epoxy resin, polyimide, polyethylene and silicon oxycarbide (SiOC). When the organic layer and the inorganic layer are stacked in multiple layers, a movement path of moisture or oxygen becomes longer compared to a single layer, so that the permeation of moisture and oxygen affecting the light-emitting element layer 30 may be effectively blocked.

The display panel may have a top emission type structure as shown in FIG. 2, a bottom emission type structure as shown in FIG. 3 or dual-side emission type, depending on an emission direction of light which is emitted from the light emitting diode, but are not limited thereto.

In the top emission type display panel, as shown in FIG. 2, light from the light-emitting element layer 30 is emitted to the outside through the second electrode 34, the encapsulation layer 40, and the color filter 50 (as shown by the arrows in FIG. 2). In the top emission type display panel, the first electrode 32 may also serve as a reflective layer to increase light efficiency, and the second electrode 34 may be implemented as a transparent or translucent electrode. In the top emission type display panel, a distance between the first electrode 32 and the second electrode 34 may be set to be different for each color of the plurality of sub-pixels, such as sub-pixels SP1, SP2, and SP3 or the like, to achieve a microcavity effect. When the microcavity is used, light reflected between the electrodes 32 and 34 undergoes constructive interference, which increases the amplitude at the wavelength of the light, thereby increasing the amount of light emitted to the outside in the top emission type.

In the bottom emission type display panel, as shown in FIG. 3, light from the light-emitting element layer 30 is emitted to the outside through the first electrode 32, the color filter 50, the circuit layer 20, and the substrate 10 (as shown by the arrows in FIG. 3). In the bottom emission type display panel, the second electrode 34 may also serve as a reflective layer to increase light efficiency, and the first electrode 32 may be implemented as a transparent or translucent electrode.

Although not being shown in the drawing, in the dual-side emission type, light emitted from the light emitting diode is emitted to an upper portion and a lower portion of the substrate 10 on which the light emitting diode is disposed. In the case of the dual-side emission type, the first electrode 32 and the second electrode 34 may both be formed of a transparent conductive material to allow the light emitted from the light emitting diode to travel to the upper portion and the lower portion of the substrate 10. In the exemplary embodiment of FIG. 2, the color filter 50 may be disposed over the encapsulation layer 40. In the exemplary embodiment of FIG. 3, the color filter 50 may be disposed between the first electrode 32 of the light-emitting element layer 30 and the circuit layer 20.

In order to reduce light of a specific wavelength, e.g., blue light, that adversely affects a user, the reflective layer may have a structure as shown in FIG. 4.

FIG. 4 is a cross-sectional view illustrating a cross-sectional structure of a reflective layer capable of absorbing light in an absorption wavelength band.

Referring to FIG. 4, the reflective layer may include an incident-side metal layer 301, a reflective-side metal layer 302, and a transparent intermediate layer 303 interposed between the incident-side metal layer 301 and the reflective-side metal layer 302. The three-layer structure as shown in FIG. 4 may be provided only in the specific sub-pixel, e.g., blue sub-pixel SP3, or in each of the sub-pixels SP1, SP2, and SP3, and the present disclosure is not limited thereto. Specifically, the three-layer structure as shown in FIG. 4 may be applied to any one of the first electrode and the second electrode, or a reflective layer disposed below the first electrode, and the present disclosure is not limited thereto.

Each of the incident-side metal layer 301 and the reflective-side metal layer 302 may be made of a metal such as silver (Ag), gold (Au), or aluminum (Al), or the like. The transparent intermediate layer 303 may be a single layer selected from a transparent conductive oxide such as indium zinc oxide (IZO) or indium tin oxide (ITO), an inorganic insulating material such as silicon nitride (SiNx) or silicon oxide (SiO₂), and an organic insulating material such as polyimide (PI), or may have a stacked structure of two or more thereof, and the present disclosure is not limited thereto. The transparent intermediate layer 303 may have a transmittance of about 50% or more.

Light may be incident on the incident-side metal layer 301. The light then enters the transparent intermediate layer 303 through the incident-side metal layer 301. In the light that passes through the transparent intermediate layer 303 and proceeds to the reflective-side metal layer 302, in an absorption wavelength band, e.g., the wavelength band of blue light, wavelengths that adversely affect the user's eye health are absorbed by the transparent intermediate layer 303, while light of other wavelengths passes through the transparent intermediate layer 303 and is reflected from the reflective-side metal layer 302. The wavelength band of blue light is 400 nm to 490 nm. In the visible light band, short wavelengths that adversely affect the user's eye health may be short wavelengths (e.g., particularly 400 nm to 450 nm) in the blue wavelength band. Such short wavelengths may be absorption wavelengths that are absorbed within the reflective layer and/or the electrodes including the reflective layer.

Depending on a thickness t3 of the transparent intermediate layer 303, at least some of the light of a specific wavelength, e.g., the light in the blue wavelength band, may be absorbed in the reflective layer by destructive interference rather than constructive interference between the incident-side metal layer 301 and the reflective-side metal layer 302. Light other than the absorption wavelength may resonate between the incident-side metal layer 301 and the reflective-side metal layer 302, increasing in amplitude by constructive interference, and thus may pass through the incident-side metal layer 301.

As an example, a thickness t1 of the incident-side metal layer 301 on which light is incident is smaller than a thickness t2 of the reflective-side metal layer 302 from which light is reflected. For example, the thickness t1 of the incident-side metal layer 301 may be between 50 Å and 450 Å, and the thickness t2 of the reflective-side metal layer 302 may be between 500 Å and 2000 Å, but are not limited thereto.

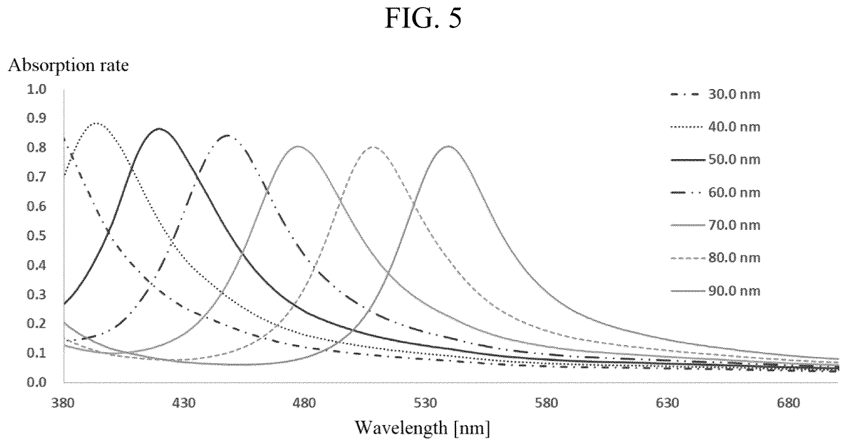

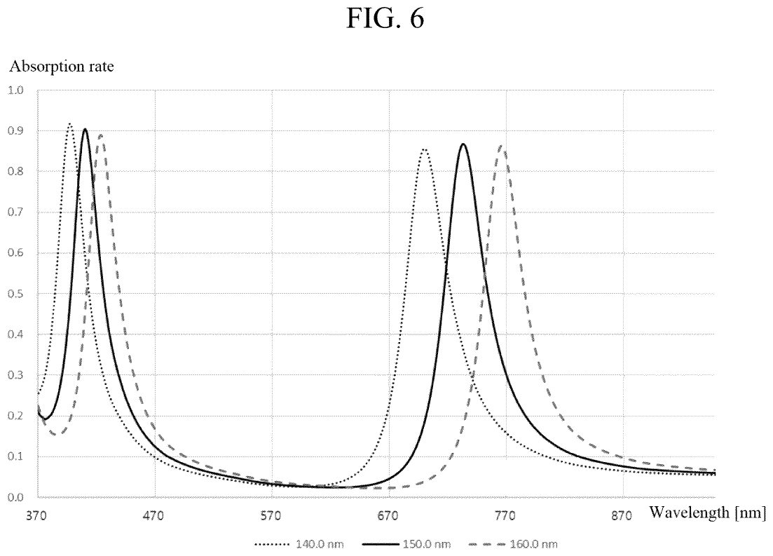

The transparent intermediate layer 303 in the reflective layer may absorb light of a specific wavelength band depending on its thickness t3. FIGS. 5 and 6 are graphs illustrating the variation of a light absorption rate for each wavelength band depending on the thickness t3 of the transparent intermediate layer 303 when the thickness t1 of the incident-side metal layer 301 is 20 nm and the thickness t2 of the reflective-side metal layer 302 is 100 nm. In FIGS. 5 and 6, the horizontal axis is the wavelength of light [nm] and the vertical axis is the absorption rate of light, and the different curves represent different thicknesses of the transparent intermediate layer 303, e.g., the thickness of the transparent intermediate layer 303 may be 30 nm, 40 nm, 50 nm, 60 nm, 70 nm, 80 nm, 90 nm, and the like.

As can be seen in FIG. 5, the blue wavelength band may be absorbed in the reflective layer when the thickness of the transparent intermediate layer 303 is between 50 nm and 80 nm. Further, as shown in FIG. 6, the blue wavelength band may be absorbed in the reflective layer when the thickness of the transparent intermediate layer 303 is between 140 nm and 160 nm. Therefore, in order to reduce light in the blue wavelength band, the thickness t3 of the transparent intermediate layer 303 may be set to a thickness, between 50 nm and 80 nm or between 140 nm and 160 nm, which may selectively absorb light of the absorption wavelength, and the present disclosure is not limited thereto.

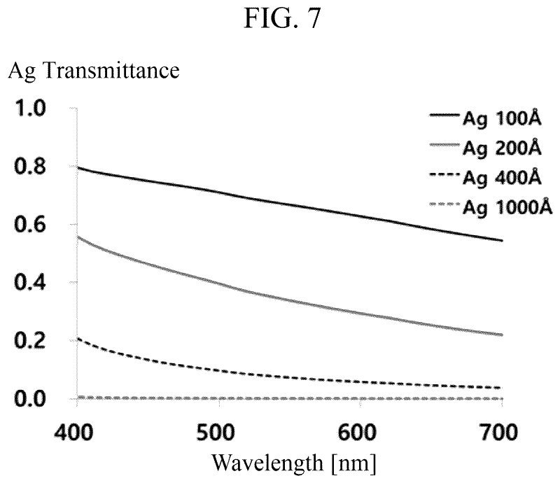

Depending on the thicknesses t1 and t2 of the first and second metal layers 301 and 302, a transmittance may vary for each wavelength of light. For example, FIG. 7 shows a transmittance for each wavelength of light when the thickness of silver (Ag) is 100 Å, 200 Å, 400 Å, and 1000 Å. In FIG. 7, the horizontal axis is the wavelength of light [nm] and the vertical axis is the transmittance of light. When the transmittance is “1”, 100% of the incident light passes through the silver (Ag), and when the transmittance is “0.2”, 20% of the incident light passes through the silver (Ag). As the thickness of the metal increases, the transmittance of light decreases, while the reflectance of light increases. In FIG. 7, when the thickness of silver (Ag) is 1000 Å, the transmittance is 0.0 for all wavelengths, that is, the thicker the first and second metal layers 301 and 302 are, the lower their transmittance becomes.

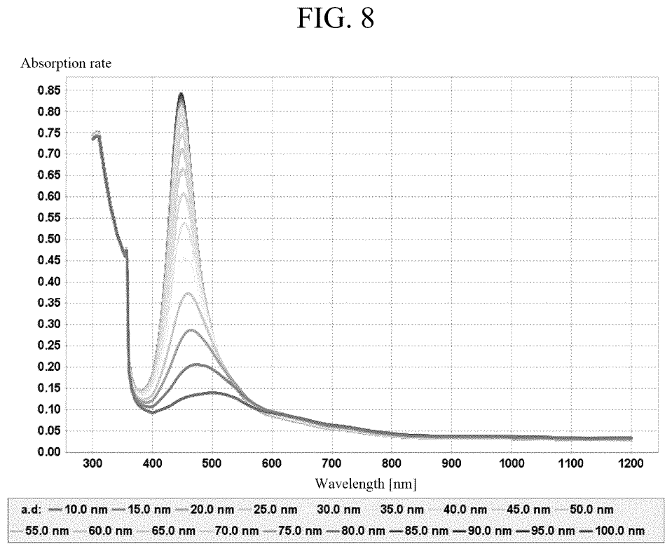

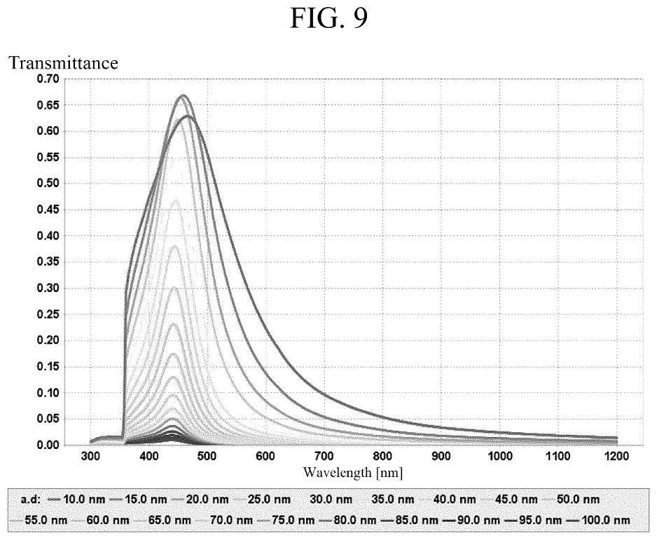

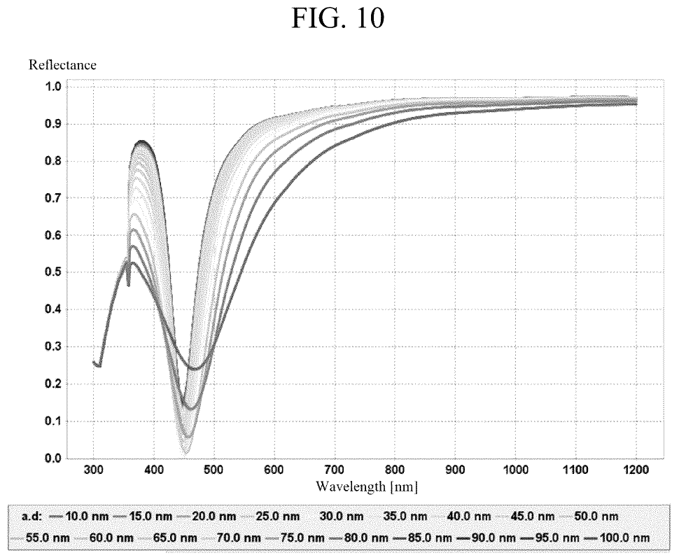

FIG. 8 is a graph illustrating an absorption rate of light for each wavelength depending on the thickness t2 of the reflective-side metal layer 302 in the reflective layer having a three-layer structure as shown in FIG. 4. In FIG. 8, the horizontal axis is the wavelength of light [nm] and the vertical axis is the absorption rate of light for each wavelength. FIG. 9 is a graph illustrating a transmittance of light for each wavelength depending on the thickness t2 of the reflective-side metal layer 302 in the reflective layer having a three-layer structure as shown in FIG. 4. In FIG. 9, the horizontal axis is the wavelength of light [nm] and the vertical axis is the transmittance of light for each wavelength. FIG. 10 is a graph illustrating a reflectance of light for each wavelength depending on the thickness t2 of the reflective-side metal layer 302 in the reflective layer having a three-layer structure as shown in FIG. 4. In FIG. 10, the horizontal axis is the wavelength of light [nm] and the vertical axis is the reflectance of light for each wavelength. In the experiments of FIGS. 8 to 10, the metal of the reflective-side metal layer 302 is silver (Ag), and the present disclosure is not limited thereto, other metals that also have this reflective function may be used as well.

The experimental result of FIG. 8 shows that with the thickness t3 of the transparent intermediate layer 303 fixed at 60 nm and the absorption wavelength band of the transparent intermediate layer 303 set at the level of 450 nm, when the thickness t2 of the reflective-side metal layer 302 is changed while the thickness t1 of the incident-side metal layer 301 is fixed at 20 nm, the absorption rate of light converges to a highest value at the thickness t2 of 50 nm or more.

When the thickness t2 of the reflective-side metal layer 302 is equal to or similar to the thickness t1 of the incident-side metal layer 301, for example, when t1=t2=20 nm, constructive interference may occur in the reflective layer, thereby maximizing the transmittance of light passing through the reflective layer. As can be seen in FIG. 9, when the thickness t2 of the reflective-side metal layer 302 is 20 nm, the transmittance of a wavelength of 450 nm passing through the reflective layer is maximum.

Only wavelengths that adversely affect the user's eyes should be selectively absorbed, while light of other wavelengths should be reflected by the reflective layer. For this purpose, it is desirable to increase the thickness t2 of the reflective-side metal layer 302. In the experimental result of FIG. 7, when the thickness of silver (Ag) is 400 Å=40 nm, the transmittance of light having a wavelength of 450 nm is about 10%. This means that when the reflective-side metal layer 302 is made of silver (Ag) and its thickness is 40 nm, the light passing through the reflective-side metal layer 302, i.e., the light loss, is 10%. Therefore, in order to minimize the light loss for wavelengths other than the absorption wavelength band, as shown in FIG. 10, the thickness t2 of the reflective-side metal layer 302 is preferably at least 50 nm or more, for example, between 500 Å and 2000 Å.

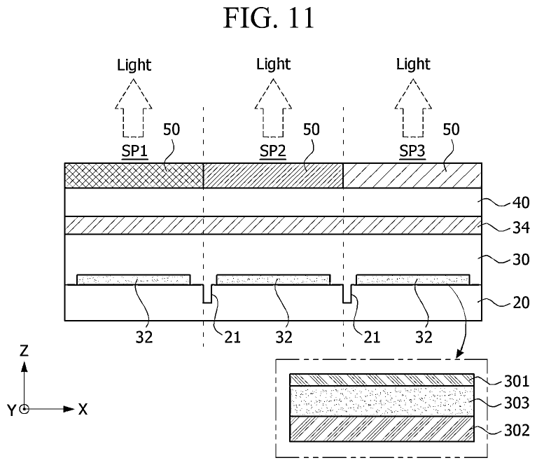

FIG. 11 is a cross-sectional view illustrating another example to which the reflective layer shown in FIG. 4 is applied in a top emission type display panel. In FIG. 11, the substrate is omitted.

Referring to FIG. 11, the circuit layer 20 may include an insulating layer adjacent to the first electrodes 32 of the light-emitting element layer 30. The insulating layer may include a trench 21 recessed at a boundary between the plurality of sub-pixels, such as sub-pixels SP1, SP2, and SP3.

The light-emitting element layer 30 may be disposed on the circuit layer 20. The light-emitting element layer 30 includes the plurality of first electrodes 32 disposed on the insulating layer of the circuit layer 20, and the second electrode 34 opposite to the first electrodes 32 with the emission layer interposed therebetween. The light-emitting element layer 30 may include the white light-emitting element disposed in the plurality of sub-pixels, such as sub-pixels SP1, SP2, and SP3. The white light-emitting element may emit light when a voltage applied to the first electrode 32 and the second electrode 34 is greater than its threshold voltage.

In each of the plurality of sub-pixels, such as sub-pixels SP1, SP2, and SP3, the first electrode 32 may include the incident-side metal layer 301, the reflective-side metal layer 302, and the transparent intermediate layer 303 interposed between the metal layers 301 and 302, as shown in FIG. 4. Light from the white light-emitting element traveling toward the rear surface of the display panel passes through the incident-side metal layer 301 and the transparent intermediate layer 303 of the first electrode 32 to reach the reflective-side metal layer 302, is reflected from the reflective-side metal layer 302, and is then emitted toward the front surface of the display panel through the transparent intermediate layer 303, the incident-side metal layer 301, the emission layer of the white light-emitting element, the second electrode 34, the encapsulation layer 40, and the color filter 50. Alternatively, only the first electrode 32 of the blue sub-pixel SP3 may be formed as the reflective layer of the three-layer structure shown in FIG. 4, and the present disclosure is not limited thereto. In this case, the first electrodes 32 of the red and green sub-pixels SP1 and SP2 may be formed of a single layer metal, or a stacked structure and/or material different from the reflective layer shown in FIG. 4. In other implementations, only the red sub-pixel SP1 or the green sub-pixel SP2 may be formed as a reflective layer with a three-layer structure as shown in FIG. 4.

For example, when light in the red wavelength band needs to be reduced or minimized, the reflective layer of the three-layer structure shown in FIG. 4 may be formed only in the red sub-pixel SP1 which is a first sub-pixel. When light in the green wavelength band needs to be reduced or minimized, the reflective layer of the three-layer structure shown in FIG. 4 may be formed only in the green sub-pixel SP2 which is a second sub-pixel. When light in the blue wavelength band needs to be reduced or minimized, the reflective layer of the three-layer structure shown in FIG. 4 may be formed only in the blue sub-pixel SP3 which is a third sub-pixel, and the present disclosure is not limited thereto.

In some or all of the sub-pixels SP1, SP2, and SP3, the incident-side metal layer 301 is thinner than the reflective-side metal layer 302. In some or all of the sub-pixels SP1, SP2, and SP3, the thickness of the transparent intermediate layer 303 may be set to a thickness that absorbs light of a specific wavelength, e.g., light in the blue wavelength band, particularly, light of short wavelengths within the blue wavelength band. The absorption wavelength band may be selected by the thickness of the transparent intermediate layer 303, and the light absorption rate, light transmittance, and light reflectance may be selected by the thicknesses of the metal layers 301 and 302.

As shown in FIG. 2, the encapsulation layer 40 may be disposed on the light-emitting element layer 30, and the color filters 50 may be disposed on the encapsulation layer 40. In the light incident on the color filter 50 of each of the sub-pixels SP1, SP2, and SP3, the amount of short-wavelength light in the blue wavelength band is reduced or minimized by the three-layer reflective layer structure of the first electrode 32.

A red color filter 50 disposed in the red sub-pixel SP1 may transmit light in a red wavelength band of visible light from the white light-emitting element and block light in other wavelength bands. A green color filter 50 disposed in the green sub-pixel SP2 may transmit light in a green wavelength band of visible light from the white light-emitting element and block light in other wavelength bands. A blue color filter 50 disposed in the blue sub-pixel SP3 may transmit light in the blue wavelength band of visible light from the white light-emitting element and block light in other wavelength bands.

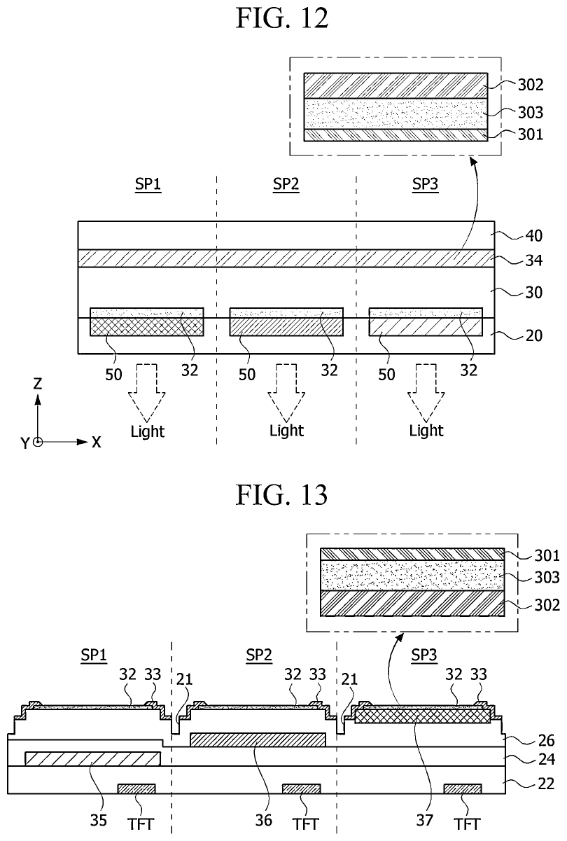

FIG. 12 is a cross-sectional view illustrating another example to which the reflective layer shown in FIG. 4 is applied in a bottom emission type display panel. In FIG. 12, the substrate is omitted.

Referring to FIG. 12, the light-emitting element layer 30 may be disposed on the circuit layer 20, and the encapsulation layer 40 may be disposed on the light-emitting element layer 30. In the circuit layer 20, the insulating layer in contact with the light-emitting element layer 30 may include the trench, which is omitted from the drawing. The light-emitting element layer 30 includes the plurality of first electrodes 32 disposed on the insulating layer of the circuit layer 20, and the second electrode 34 opposite to the first electrodes 32 with the emission layer of the white light-emitting element interposed therebetween.

The first electrodes 32 may be transparent or translucent electrodes through which light from the white light-emitting element passes. The color filters 50 may be disposed below the first electrodes 32 of the light-emitting element layer 30. The red color filter 50 disposed in the red sub-pixel SP1 may transmit light in the red wavelength band of visible light from the white light-emitting element and block light in other wavelength bands. The green color filter 50 disposed in the green sub-pixel SP2 may transmit light in the green wavelength band of visible light from the white light-emitting element and block light in other wavelength bands. The blue color filter 50 disposed in the blue sub-pixel SP3 may transmit light in the blue wavelength band of visible light from the white light-emitting element and block light in other wavelength bands.

In each of the plurality of sub-pixels, such as sub-pixels SP1, SP2, and SP3, the second electrode 34 may include the reflective layer having a three-layer structure, i.e., the incident-side metal layer 301, the reflective-side metal layer 302, and the transparent intermediate layer 303 interposed between the metal layers 301 and 302, as shown in FIG. 4. In the light incident on the color filter 50 of each of the sub-pixels SP1, SP2, and SP3, the amount of short-wavelength light in the blue wavelength band is reduced or minimized by the three-layer reflective layer structure of the second electrode 34.

In each of the plurality of sub-pixels, such as the sub-pixels SP1, SP2, and SP3, the incident-side metal layer 301 is thinner than the reflective-side metal layer 302. In each of the plurality of sub-pixels, such as sub-pixels SP1, SP2, and SP3, the thickness of the transparent intermediate layer 303 may be set to a thickness that absorbs light in the blue wavelength band, particularly, light of short wavelengths within the blue wavelength band. The absorption wavelength band may be selected by thickness of the transparent intermediate layer 303, and the light absorption rate, light transmittance, and light reflectance may be selected by the thicknesses of the metal layers 301 and 302.

Light from the white light-emitting element traveling toward the front surface of the display panel passes through the incident-side metal layer 301 and the transparent intermediate layer 303 of the second electrode 34 to reach the reflective-side metal layer 302, is reflected from the reflective-side metal layer 302, and then is emitted toward the rear surface of the display panel through the transparent intermediate layer 303, the incident-side metal layer 301, the emission layer of the white light-emitting element, the first electrode 32, the color filter 50, the circuit layer 20, and the substrate.

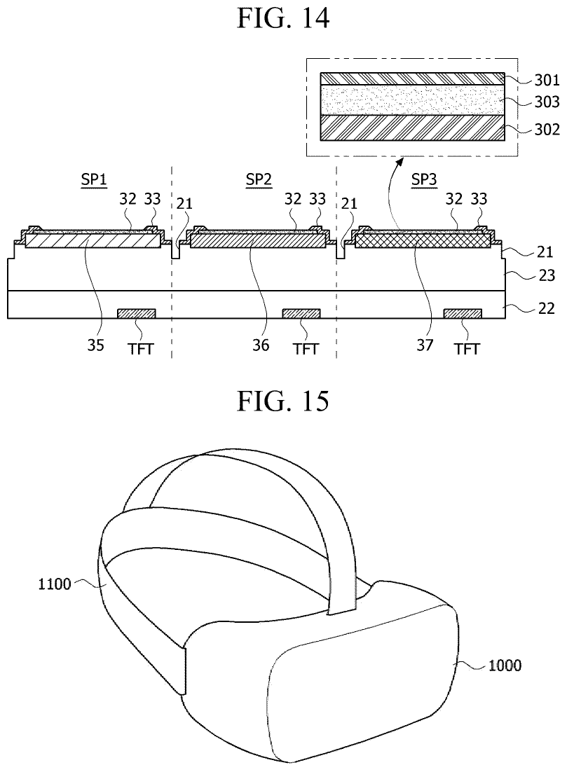

FIGS. 13 and 14 are cross-sectional views illustrating still another example to which the reflective layer shown in FIG. 4 is applied in a top emission type display panel. In FIGS. 13 and 14, the substrate, the encapsulation layer, the color filter, and the like are omitted. The display panel shown in FIG. 13 provides a microcavity effect in each of the plurality of sub-pixels, such as sub-pixels SP1, SP2, and SP3.

In FIGS. 13 and 14, “TFT” denotes a thin film transistor that is disposed in the circuit layer to be electrically connected to the light-emitting element and supplies a current to the light-emitting element.

A light-emitting element, a thin film transistor (TFT) for driving the light emitting element, and the like may be disposed in each of the plurality of sub-pixels, such as sub-pixels SP1, SP2, and SP3. A plurality of light emitting elements may be defined differently depending on the type of display panel. For example, when the display panel is an inorganic light emitting display panel, the light emitting element may be a light emitting diode (LED) or a micro light emitting diode (micro LED), and when the display panel is an organic light emitting display panel, the light emitting element may be an organic light emitting diode (OLED), and embodiments of the present disclosure are not limited thereto.

Referring to FIG. 13, the circuit layer may include a first insulating layer 22 covering the TFT, a second insulating layer 24 disposed on the first insulating layer 22, and a third insulating layer 26 disposed on the second insulating layer 24. A reflective layer 35 of the red sub-pixel SP1 may be disposed on the first insulating layer 22. A reflective layer 36 of the green sub-pixel SP2 may be disposed on the second insulating layer 24. A reflective layer 37 of the blue sub-pixel SP3 may be disposed on the third insulating layer 26. For example, each of the first insulating layer 22, the second insulating layer 24 and the third insulating layer 26 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The light-emitting element layer may further include a fence. In each of plurality of sub-pixels, such as the sub-pixels SP1, SP2, and SP3, the edge of the first electrode 32 may be covered by a fence 33. The fence 33 is an insulating layer pattern that covers the top surface and the side surface of the edge of the first electrode 32. The fence 33 may be formed of an inorganic insulating material such as SiNx, SiO2, or the like. In the absence of the fence 33, the light-emitting element may be degraded due to the lightning rod effect generated by an electric field concentrated at the edge and corner of the first electrode 32.

In order to increase the amount of light of each color by using the micro cavity effect in each of the plurality of sub-pixels, such as sub-pixels SP1, SP2, and SP3, the thickness of the insulating layer between the first electrode 32 and the reflective layers 35, 36, and 37 may be different for each sub-pixel. For example, the insulating layers 24 and 26 between the first electrode 32 and the reflective layer 35 in the red sub-pixel SP1 are thicker than the insulating layer 26 between the first electrode 32 and the reflective layer 36 in the green sub-pixel SP2. In the blue sub-pixel SP3, the first electrode 32 and the reflective layer 37 may be in contact with each other without a gap.

The reflective layers 35, 36, and 37 of the plurality of sub-pixels, such as sub-pixels SP1, SP2, and SP3 may be substantially the same as the reflective layer of the three-layer structure shown in FIG. 4. Alternatively, only the reflective layer 37 of the blue sub-pixel SP3 may be formed as the reflective layer of the three-layer structure shown in FIG. 4. In this case, the reflective layers 35 and 36 of the red and green sub-pixels SP1 and SP2 may be formed of a single layer metal, or a stacked structure and/or material different from the reflective layer shown in FIG. 4. In other implementations, only the reflective layers 35 or 36 of the red or green sub-pixels SP1 and SP2 may be formed as a reflective layer with a three-layer structure as shown in FIG. 4.

Referring to FIG. 14, the first electrode 32 and the reflective layers 35, 36, and 37 in the sub-pixels SP1, SP2, and SP3 may be in contact with each other. In this embodiment, the reflective layers 35, 36, and 37 of the sub-pixels SP1, SP2, and SP3 may be substantially the same as the reflective layer of the three-layer structure shown in FIG. 4. Alternatively, only the reflective layer 37 of the blue sub-pixel SP3 may be formed as the reflective layer of the three-layer structure shown in FIG. 4. In this case, the reflective layers 35 and 36 of the red and green sub-pixels SP1 and SP2 may be formed of a single layer metal, or a stacked structure and/or material different from the reflective layer shown in FIG. 4.

For example, when light in the red wavelength band needs to be reduced or minimized, the reflective layer of the three-layer structure shown in FIG. 4 may be formed only in the reflective layer 35 of the red sub-pixel SP1. When light in the green wavelength band needs to be reduced or minimized, the reflective layer of the three-layer structure shown in FIG. 4 may be formed only in the reflective layer 36 of the green sub-pixel SP2. When light in the blue wavelength band needs to be reduced or minimized, the reflective layer of the three-layer structure shown in FIG. 4 may be formed only in the reflective layer 37 of the blue sub-pixel SP3, and the present disclosure is not limited thereto.

The display panel of the above-described embodiments may implement a left-eye screen and a right-eye screen of a personal immersive device.

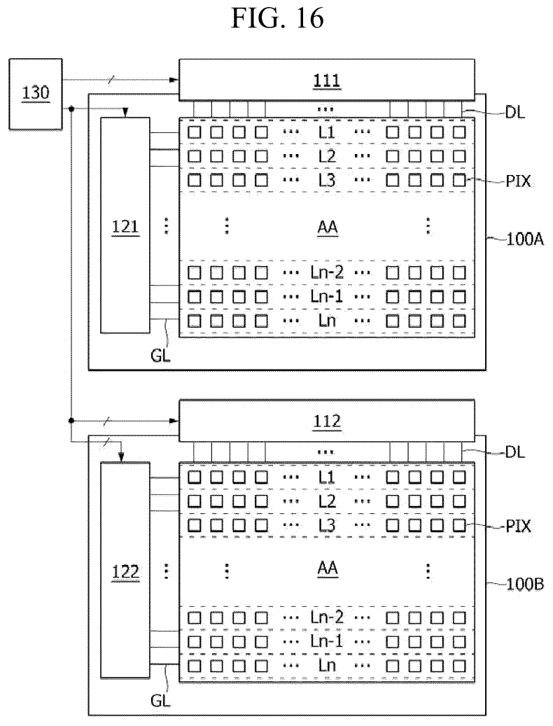

FIG. 15 is a diagram illustrating an example of the appearance of a personal immersive device. The appearance of a personal immersive device is not limited to FIG. 15.

Referring to FIG. 15, the personal immersive device may be manufactured in an HMD type exterior design including a main body 1000 and a head-mounted band 1100.

The main body 1000 may include the display panel of the above-described embodiment, a lens disposed to face a screen of the display panel, a display panel driver, a system controller, a plurality of sensors, and the like. The main body 1000 may further include a camera. The lens may include an eyepiece or a fisheye lens. The display panel driver receives the pixel data of the input image and drives the pixels to display the input image on the pixels of the display panel.

The system controller may include an external device interface connected to a sensor, a camera, or the like and connected to a memory or an external video source, a user interface for receiving a user command, and one or more processors connected to a power supply that generates power. The sensors include various sensors such as a gyro sensor and an acceleration sensor. The sensors transmit their outputs to the system controller. The system controller may receive the outputs of the sensors, move the pixel data of an image displayed on the pixels of the display panel in synchronization with the user's movement, and execute a Foveated Rendering algorithm that follows the user's gaze.

The personal immersive device may be implemented using a mobile terminal system such as a smartphone. In this case, a left-eye image and a right-eye image may be displayed together on the display panel of the mobile terminal system. The smartphone supports VR mode, which is an example of a partial mode. In the VR mode of the smartphone, the left-eye image and the right-eye image may be displayed together in a separate manner on a single display panel. In this case, the configuration of the main body 1000 in FIG. 15 is simplified, and the mobile terminal system supporting the VR mode may be detachably mounted on the main body 1000.

FIG. 16 is a block diagram illustrating an example of a display device applicable to a personal immersive device.

Referring to FIG. 16, the display device may include a first display panel 100A on which a left-eye image is displayed, and a second display panel 100B on which a right-eye image is displayed.

The display panels 100A and 100B include data lines DL, gate lines GL, and the pixels PIX. A screen of the display panels 100A and 100B includes a pixel array on which an image is displayed. The pixel array includes pixel lines L1 to Ln into which pixel data is written by being sequentially scanned by scan pulses shifted along a scanning direction.

The display panel driver may include data drivers 111 and 112, gate drivers 121 and 122, a controller 130, and the like. The data drivers 111 and 112 and the gate drivers 121 and 122 may be separated for each of the display panels 100A and 100B, while the controller 130 may be shared. The data drivers 111 and 112 convert the pixel data inputted from the controller 130 into voltage or current to supply data signals to the pixels. The gate drivers 121 and 122 sequentially output scan pulses synchronized with the data signals outputted from the data drivers 111 and 112 under the control of the controller 130.

The objects to be achieved by the present disclosure, the means for achieving the objects, and effects of the present disclosure described above do not specify essential features of the claims, and thus, the scope of the claims is not limited to the disclosure of the present disclosure.

It will be apparent to those skilled in the art that various modifications and variations can be made in the display panel and the personal immersive device including the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display panel, comprising:
a light-emitting element configured to emit light in response to a voltage applied to a first electrode and a second electrode,
wherein any one of the first electrode and the second electrode includes:
an incident-side metal layer on which light from the light-emitting element is incident;
a reflective-side metal layer from which the light is reflected; and
a transparent intermediate layer interposed between the incident-side metal layer and the reflective-side metal layer,
wherein the incident-side metal layer is thinner than the reflective-side metal layer.

2. The display panel of claim 1, wherein the incident-side metal layer has a thickness between 50 Å and 450 Å, and the reflective-side metal layer has a thickness between 500 Å and 2000 Å.

3. The display panel of claim 1, wherein each of the incident-side metal layer and the reflective-side metal layer includes metal selected from silver (Ag), gold (Au), and aluminum (Al).

4. The display panel of claim 1, wherein the transparent intermediate layer has a thickness between 50 nm and 80 nm or a thickness between 140 nm and 160 nm.

5. The display panel of claim 4, wherein the transparent intermediate layer includes a single layer selected from a transparent conductive oxide, an inorganic insulating material, and an organic insulating material, or a stacked structure in which at least two of the transparent conductive oxide, the inorganic insulating material, and the organic insulating material are stacked.

6. A display panel, comprising:
a light-emitting element layer in which a light-emitting element is disposed;
a circuit layer disposed below the light-emitting element layer and including a pixel circuit configured to drive the light-emitting element; and
an encapsulation layer disposed on the light-emitting element layer,
wherein the light-emitting element layer includes:
a plurality of first electrodes disposed respectively in a plurality of sub-pixels and separated between the plurality of sub-pixels; and
a second electrode shared by the plurality of sub-pixels,
wherein any one of the first electrode and the second electrode includes:
an incident-side metal layer on which light from the light-emitting element is incident;
a reflective-side metal layer from which the light is reflected; and
a transparent intermediate layer interposed between the incident-side metal layer and the reflective-side metal layer,
wherein the incident-side metal layer is thinner than the reflective-side metal layer, and the plurality of sub-pixels comprise a red sub-pixel, a green sub-pixel, and a blue sub-pixel, and
wherein the first electrode of at least the blue sub-pixel includes the incident-side metal layer, the reflective-side metal layer and the transparent intermediate layer.

7. The display panel of claim 6, wherein the light-emitting element includes a white light-emitting element disposed in the red sub-pixel, the green sub-pixel, and the blue sub-pixel to emit white light,
the red sub-pixel includes a red color filter disposed on the encapsulation layer or below the first electrode of the red sub-pixel,
the green sub-pixel includes a green color filter disposed on the encapsulation layer or below the first electrode of the green sub-pixel, and
the blue sub-pixel includes a blue color filter disposed on the encapsulation layer or below the first electrode of the blue sub-pixel.

8. The display panel of claim 6, wherein the circuit layer includes an insulating layer adjacent to the first electrodes, wherein the insulating layer is recessed between the plurality of sub-pixels, and
the light-emitting element layer includes an insulating layer pattern that covers a top surface and a side surface of an edge of each of the first electrodes.

9. The display panel of claim 6, wherein the incident-side metal layer has a thickness between 50 Å and 450 Å, the reflective-side metal layer has a thickness between 500 Å and 2000 Å, and the transparent intermediate layer has a thickness between 50 nm and 80 nm or a thickness between 140 nm and 160 nm.

10. The display panel of claim 9, wherein each of the incident-side metal layer and the reflective-side metal layer includes metal selected from silver (Ag), gold (Au), and aluminum (Al), and
the transparent intermediate layer includes a single layer selected from a transparent conductive oxide, an inorganic insulating material, and an organic insulating material, or a stacked structure in which at least two of the transparent conductive oxide, the inorganic insulating material, and the organic insulating material are stacked.

11. The display panel of claim 1, further comprising:
a light-emitting element layer in which the light-emitting element is disposed;
a circuit layer disposed below the light-emitting element layer and including a pixel circuit configured to drive the light-emitting element; and
an encapsulation layer disposed on the light-emitting element layer,
wherein the light-emitting element layer includes:
a plurality of the first electrodes disposed respectively in a plurality of sub-pixels and separated between the plurality of sub-pixels; and
the second electrode shared by the plurality of sub-pixels,
wherein the plurality of sub-pixels include a plurality of reflective layers disposed below the first electrodes of the plurality of sub-pixels,
wherein at least one of the plurality of reflective layers includes:
the incident-side metal layer, the reflective-side metal layer, and the transparent intermediate layer.

12. The display panel of claim 11, wherein the plurality of sub-pixels comprise a red sub-pixel, a green sub-pixel, and a blue sub-pixel,
wherein the red sub-pixel includes a first reflective layer disposed below the first electrode of the red sub-pixel,
the green sub-pixel includes a second reflective layer disposed below the first electrode of the green sub-pixel, and
the blue sub-pixel includes a third reflective layer disposed below the first electrode of the blue sub-pixel,
wherein at least the third reflective layer of the first reflective layer, the second reflective layer, the third reflective layer includes the incident-side metal layer, the reflective-side metal layer and the transparent intermediate layer.

13. The display panel of claim 12, wherein each of the first reflective layer, the second reflective layer, and the third reflective layer includes the incident-side metal layer, the reflective-side metal layer, and the transparent intermediate layer.

14. The display panel of claim 12, wherein an insulating layer between the first reflective layer and the first electrode of the red sub-pixel is thicker than an insulating layer between the second reflective layer and the first electrode of the green sub-pixel.

15. The display panel of claim 12, wherein the third reflective layer and the first electrode of the blue sub-pixel are in contact with each other.

16. The display panel of claim 12, wherein the light-emitting element includes a white light-emitting element disposed in the red sub-pixel, the green sub-pixel, and the blue sub-pixel to emit white light,
the red sub-pixel includes a red color filter disposed on the encapsulation layer or below the first electrode of the red sub-pixel,
the green sub-pixel includes a green color filter disposed on the encapsulation layer or below the first electrode of the green sub-pixel, and
the blue sub-pixel includes a blue color filter disposed on the encapsulation layer or below the first electrode of the blue sub-pixel.

17. The display panel of claim 11, wherein the circuit layer includes an insulating layer adjacent to the first electrodes, wherein the insulating layer is recessed between the plurality of sub-pixels, and the light-emitting element layer includes an insulating layer pattern that covers a top surface and a side surface of an edge of each of the first electrodes.

18. The display panel of claim 11, wherein the incident-side metal layer has a thickness between 50 Å and 450 Å, the reflective-side metal layer has a thickness between 500 Å and 2000 Å, and the transparent intermediate layer has a thickness between 50 nm and 80 nm or a thickness between 140 nm and 160 nm.

19. The display panel of claim 18, wherein each of the incident-side metal layer and the reflective-side metal layer includes metal selected from silver (Ag), gold (Au), and aluminum (Al), and
the transparent intermediate layer includes a single layer selected from a transparent conductive oxide, an inorganic insulating material, and an organic insulating material, or a stacked structure in which at least two of the transparent conductive oxide, the inorganic insulating material, and the organic insulating material are stacked.

20. A personal immersive device, comprising:
a first display panel in which a plurality of red sub-pixels, a plurality of green sub-pixels, and a plurality of blue sub-pixels each including a light-emitting element and a pixel circuit configured to drive the light-emitting element are disposed; and
a second display panel in which a plurality of red sub-pixels, a plurality of green sub-pixels, and a plurality of blue sub-pixels each including a light-emitting element and a pixel circuit configured to drive the light-emitting element are disposed;
wherein the light-emitting element of the first and second display panels emits light in response to a voltage applied to a first electrode and a second electrode,
wherein any one of the first electrode and the second electrode, or a reflective layer disposed below the first electrode includes:
an incident-side metal layer on which light from the light-emitting element is incident;
a reflective-side metal layer from which the light is reflected; and
a transparent intermediate layer interposed between the incident-side metal layer and the reflective-side metal layer, and
wherein the incident-side metal layer is thinner than the reflective-side metal layer.
